(19) United States
(12) Patent Application Publication
(10) Pub. No.: US 2026/0266869 A1
(43) Pub. Date: Sep. 10, 2026

(54) DIAGNOSTIC MONITORING AND FAULT DETECTION IN VEHICLE DC POWER INTERFACES

(71) Applicant: FORD GLOBAL TECHNOLOGIES, LLC, Dearborn, MI (US)

(72) Inventors: Steven Craig Wellington, Kanata (CA); Thomas Fitzgibbons, Sunrise, FL (US); Davin Lampert, Fort Lauderdale, FL (US)

(21) Appl. No.: 19/069,908

(22) Filed: Mar. 4, 2025

(51) Int. Cl. G01R 1/04; G01R 1/20; G01R 31/28

(52) U.S. Cl. CPC G01R 1/0416; G01R 1/203; G01R 1/206; G01R 31/2806

(57) ABSTRACT

A vehicle power system and electrical connector system are disclosed, incorporating a multi-pin connector, a DC power source, and diagnostic circuitry for voltage modulation and measurement. The system designates one pin as a common potential reference, with adjacent pins capable of toggling between this reference potential and a reduced value. Additionally, the mounting tab's potential may be dynamically adjusted in coordination with circuit lines incorporating resistors. The system uses switches to pull down voltage levels for diagnostic purposes, influencing the surrounding electric field. The connector's pin arrangement includes grounded or signal pins positioned around toggling pins. In some embodiments, a designated corner pin interacts with adjacent pins, which are linked to the DC power source through resistors, for voltage control and tracking.

### TECHNICAL FIELD

This disclosure relates to power electronics and embedded system design, addressing power distribution, fault protection, and diagnostic monitoring in electronic circuits.

### BACKGROUND

Electrical connectors and printed circuit board (PCB) design are fundamental to modern electronic systems, providing the necessary electrical and mechanical interfaces between different circuit elements. Connectors serve as structured connection points that facilitate signal and power transmission across modules while allowing for modularity, serviceability, and interchangeability. They are often designed with specific pin assignments, which include power, ground, and signal lines. High-reliability connectors account for factors such as contact resistance and mechanical wear. The spacing between pins and the insulating material used in the connector housing affect the likelihood of unintended electrical interactions. Additionally, connectors may incorporate shielding to reduce electromagnetic interference (EMI).

PCB design involves layout and routing to optimize performance while minimizing unwanted electrical effects such as crosstalk, impedance mismatches, and parasitic capacitance. High-speed and high-power PCBs use controlled impedance traces, specific layer stacking methods, and grounding strategies to support stable operation. Some designs also incorporate clearance distance rules, which define the minimum allowable spacing between conductors.

### SUMMARY

A vehicle power system includes a DC power source, an electrical connector with multiple pins, and circuitry designed for diagnostic measurements. One pin shares a common potential with the DC power source, while adjacent pins can toggle between this common potential and a reduced value. The system may also toggle the potential of a mounting tab, incorporate resistors (with at least 10 kΩ resistance), and use switches for toggling. The pins are arranged in rows, with some adjacent pins positioned within the same or different rows. Grounded or signal pins may be positioned around the toggling pins, and this toggling modifies the surrounding electric field.

An electrical connector system includes a connector with multiple pins and a mounting tab, where one pin is connected to a DC power source through a circuit line. Another circuit line, incorporating a resistor, links the mounting tab and adjacent pins to the DC power source so their voltage tracks the source voltage. The system may include switches that pull down this circuit line for diagnostic measurements, and the resistor has a resistance of at least 10 kΩ. The designated pin can be a corner pin, with adjacent pins positioned between it and grounded or signal pins.

An electrical connector system includes a multi-pin electrical connector with a mounting tab and associated circuitry that dynamically adjusts the potential of the mounting tab. The circuitry toggles the potential between a value that tracks a specific pin of the connector, such as a DC power source input pin, and a reduced value.

### BRIEF DESCRIPTION OF THE DRAWINGS

FIG. 1 is a schematic diagram of a connector and associated circuitry.

FIGS. 2 and 3 are simulation results showing electric field strength between pins of a connector under different conditions.

FIG. 4 is a block diagram of a vehicle.

### DETAILED DESCRIPTION

Detailed embodiments of the present disclosure are provided herein. These embodiments serve as examples and may be implemented in various alternative forms. The figures presented are not necessarily to scale, as certain features may be exaggerated or minimized to emphasize specific details of particular components. Accordingly, the structural and functional details described should not be considered limiting but rather as illustrative examples intended to guide those skilled in the art in applying the principles of this disclosure in different implementations.

Dendritic growth and creepage in electronic modules and connectors are mechanisms in power electronics that stem from the sustained presence of an electric field, environmental contamination, and material properties. These phenomena are particularly apparent in high-voltage, high-reliability applications where insulation integrity and long-term performance are of interest. The underlying mechanisms involve electrochemical migration (ECM), dielectric degradation, and localized charge accumulation, all of which are influenced by electric field intensity, environmental factors, and material composition.

Dendritic growth occurs due to the electrochemical migration of conductive materials in the presence of moisture and an electric field. The process begins when conductive contaminants, such as salts, carbonized plastic, lead or tin from solder joints, connectors, or PCB traces, undergo anodic dissolution. This dissolution may occur at the positively biased conductor, where atoms lose electrons and enter the surrounding environment as cations. Once in solution, these cations migrate toward the negatively biased conductor under the influence of the electric field. This migration is facilitated by the presence of an electrolyte, typically water contaminated with ionic species such as chlorides, sulfates, or residual flux from soldering. The electric field provides the driving force for ion movement, and once the ions reach the cathode, they undergo reduction and redeposit as metallic filaments. Over time, these metallic deposits form dendritic structures—elongated, branched filaments that grow toward the anode. If a dendrite fully bridges the gap between conductors, a low-resistance path is established, leading to leakage currents, localized heating, and potentially a short circuit. Several factors affect the rate and severity of dendritic growth, including electric field strength, the presence of moisture, contaminants, material properties, and operating temperature. Higher potential differences across conductors enhance the driving force for ion migration, while the presence of water acts as an electrolyte medium that promotes metal dissolution and transport. Residual flux, soldering by-products, and environmental pollutants introduce mobile ionic species that facilitate ECM, and higher operating temperatures increase ion mobility and reaction kinetics, further exacerbating dendritic formation.

Creepage is a related mode that occurs when electrical conduction develops along the surface of an insulating material, such as PCB substrates, connector housings, or dielectric coatings. Unlike dendritic growth, which involves metal ion migration in an electrolyte, creepage primarily results from charge accumulation and surface conduction due to contamination and material degradation. The mechanisms leading to creepage include surface conductivity enhancement, electrostatic charging and discharge, and material aging. Over time, dust, moisture, and ionic contaminants accumulate on insulating surfaces, reducing surface resistivity and creating conductive pathways that facilitate leakage currents along the surface. Persistent electric fields cause charge accumulation on dielectric surfaces, leading to localized breakdown or arcing. Polymeric insulators and PCB substrates undergo physical and chemical degradation due to prolonged exposure to electric fields, ultra-violet (UV) radiation, and environmental contaminants. This degradation reduces the insulation resistance and increases susceptibility to creepage. Creepage distance, defined as the shortest path along an insulating surface between two conductors, is a design parameter in high-voltage electronics. Various standards specify minimum creepage distances based on operating voltage, pollution degree, and insulation category.

In power electronics, where modules remain continuously energized, the probability of experiencing dendritic growth and creepage are heightened. Power input lines and ground return paths should maintain low impedance for efficient power transfer, but the constant presence of an electric field creates conditions conducive to long-term issues. Sustained high electric fields can lower the breakdown voltage of insulating materials over time. Even before a full short circuit occurs, partial conduction due to creepage can result in significant energy dissipation, leading to thermal stress and efficiency losses. In switching power supplies and radio frequency (RF) applications, surface contamination and dendritic growth can create parasitic conduction paths that alter circuit behavior, leading to performance degradation.

Power distribution and diagnostic monitoring systems are contemplated that utilize a connector with multiple pins to manage voltages, fault detection, and system control. Various power rails, control signals, and protection components are routed to or through these pins for structured power management and diagnostic capabilities. Electronic switches, controlled by appropriate signals, selectively connect a battery to monitoring circuits, allowing for voltage measurement and fault isolation. Some systems incorporate eFuses, resistors, and diodes to manage current flow, mitigate voltage spikes, and prevent unintended conduction. Additionally, mechanical design elements, including mounting tabs and socket-integrated posts, contribute to grounding, structural stability, and electrical reliability.

In one example, a vehicle battery input, which operates at approximately 48V, is supplied through a particular pin while one or more adjacent pins are designated as inputs for vehicle battery diagnostics that are integrated with a monitoring circuit. This connection is implemented with a 10 kΩ or greater resistor to the vehicle battery input for controlled voltage monitoring. When no measurement is being taken, the vehicle battery diagnostic pins remain at the same potential as the vehicle battery input, eliminating potential for increased creepage.

Physical spacing within the connector layout provides additional fault prevention features. The distance between the vehicle battery input pin and nearest ground is about 22 mm, while the spacing between the vehicle battery input pin and other pins for signals susceptible to exposure to 48V is about 9 mm. In the event of contamination within the connector leading to unintended conduction to 48V, this system is designed to detect the fault before it propagates to other key pins.

A short circuit between the vehicle battery input pin and the vehicle battery diagnostic pins would resemble a vehicle battery input overvoltage condition but could be distinguished by comparing it to an independent vehicle battery measurement. A short occurring deeper within the connector could prematurely activate other lines before they are intended to be powered. If the short is to the vehicle battery diagnostic pins rather than directly to the vehicle battery input pin, external loading effects might obscure the fault at the voltage output diagnostic circuits. However, the issue would still be detectable through direct monitoring of the vehicle battery diagnostic pins via similar circuitry or standard techniques.

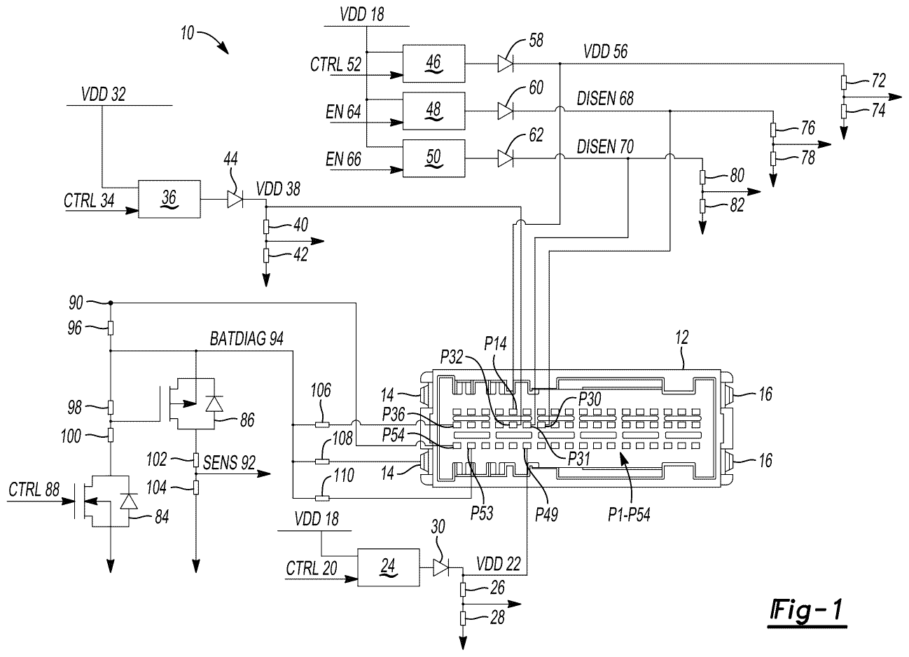

Referring to FIG. 1, a power distribution and diagnostic monitoring system 10 includes, in this example, a connector 12 with pins P1-P54 arranged in three rows of eighteen. The circuit lines represent power distribution and control signals, which link power rails, diagnostic circuits, and signal pathways to various system components. Each pin is assigned a specific function—such as power input, ground, signal transmission, or monitoring—for structured power management and fault detection. Mounting tabs 14, 16 are primarily used for mechanical stability.

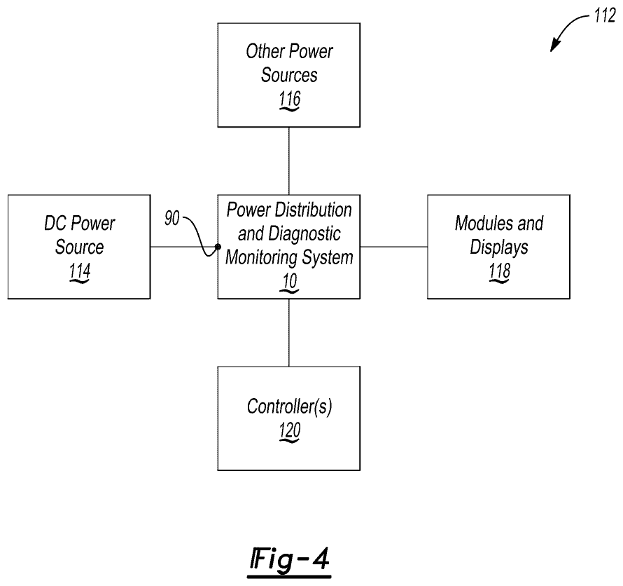

VDD 18 serves as a controlled power rail supplying voltage to various circuits. This rail connects via circuit lines to the pin P49 for power distribution. CTRL 20 controls power delivery to VDD 22, which interfaces with a power-related component (see FIG. 4) through the pin P49. To control power flow, eFuse 24 is placed in series with the VDD 18, limiting inrush current and preventing overcurrent conditions. Power is supplied to the external module only when the CTRL 20 is active, preventing unintended power application. Resistors 26, 28 function as voltage dividers and stabilize signals when not actively driven. Diode 30 prevents voltage spikes and reverse current flow.

VDD 32 provides a controlled voltage source, supplying continuous power to circuits, including another power-related component (see FIG. 4). Circuit lines link this rail to the pin P32. CTRL 34 acts as a power enable signal for the power-related component. eFuse 36 is placed in series to limit excessive current draw. When enabled, power is routed to VDD 38, the primary supply for the power-related component. Resistors 40, 42 function as voltage dividers. Diode 44 provides transient suppression and stabilizes the voltage supply under varying load conditions.

The VDD 18 also distributes power to multiple circuits, including display and control modules (see FIG. 4). Circuit lines connect this rail to the pins P14, P31, P30. eFuse 46 controls power distribution, preventing excessive current draw, while voltage controllers 48, 50 stabilize and condition output voltages for different circuit elements. CTRL 52 enables the second module by controlling power to VDD 56. Diodes 58, 60 ,62 provide reverse voltage protection, preventing unintended current flow. Similarly, EN 64 and EN 66 control two independent display circuits, working alongside DISEN 68 and DISEN 70 to synchronize and activate display interfaces. Resistors 72, 74, 76, 78, 80, 82 function as current limiters and voltage dividers.

Diagnostic monitoring circuitry is also included that incorporate switches 84, 86 to serve as controlled pathways for voltage monitoring. CTRL 88 activates the gate of the switch 84 and thus the switch 86, connecting vehicle battery input 90 to the analog-to-digital converter (ADC) circuit for voltage measurement. When asserted, the switch 84 turns on and the switch 86 turns on, allowing current flow for diagnostic measurement. When de-asserted, the switches 84, 86 turn off, isolating the vehicle battery input 90 from ADC input, SENS 92, to reduce power consumption and interference.

The vehicle battery input 90, connected to the corner pin P54, supplies power to the system 10 through the connector interface. BATDIAG 94, connected to the mounting tab 14 and pins P36, P53 which are adjacent to the pin P54, enables voltage measurement and fault detection. BATDIAG 94 could also be connected to other pins in the vicinity of the pin P54 instead of the pins P36, P53. A resistor 96 (e.g., 100 kΩ) links the vehicle battery input 90 to the BATDIAG 94, preventing direct coupling while allowing fault detection. Additional resistors 98 (e.g., 100 kΩ), 100 (e.g., 33 kΩ), 102 (e.g., 100 kΩ), 104 (e.g., 5.23 kΩ), 106 (e.g., 10 kΩ), 108 (e.g., 10 kΩ), 110 (e.g., 10 kΩ) are also included in the circuitry. If a short occurs between the pins P53, P54, the pins P36, P54, or the mounting tab 14 and pin P54, the system 10 registers an overvoltage condition at the BATDIAG 94, which can be differentiated from a genuine overvoltage by comparing it to an independent vehicle battery measurement. Other power and signal connections are distributed across the remaining pins. The pins between the pins P36, P53 and pins P14, P32, P49 are unused. Several of the pins between the mounting tab 16 and the pin P30 are used for ground.

The circuit facilitates the measurement of the vehicle battery input 90 by monitoring the voltage at the BATDIAG 94 through a controlled switching mechanism. Because the vehicle battery input 90 enters the system 10 at the pin P54, while the pins P36, P53 and the mounting tab 14 are connected to the vehicle battery input 90 via the isolation resistor 96 as mentioned above, this configuration permits the BATDIAG 94 to passively follow the vehicle battery input voltage while allowing diagnostic measurements through the ADC. The measurement process is controlled using the switches 84, 86.

When no measurement is taking place, the BATDIAG 94 is weakly connected to the vehicle battery input 90 through the resistor 96. Because no significant current flows, the BATDIAG 94 remains at approximately the same voltage as the vehicle battery input 90, thus tracking the voltage of the vehicle battery input 90. In this state, the switches 84, 86 remain off, meaning the BATDIAG 94 is isolated from the SENS 92, and no measurement is being performed. This default condition also reduces the possibility of creepage currents and prevents unnecessary power dissipation.

To initiate a measurement, the CTRL 88 is asserted, turning on the switch 84 and thus the switch 86, creating a low impedance path between the BATDIAG 94 and the resistors 102, 104. This reduces the BATDIAG 94 voltage as a function of the resistors 102, 104 and allows the ADC to sense the voltage present at this node via the SENS 92.

Once the ADC has recorded the voltage, the system de-asserts the CTRL 88, turning off the switches 84, 86, disconnecting the BATDIAG 94 from the SENS 92. With the switches 84, 86 off, the BATDIAG 94 is once again only weakly connected to the vehicle battery input 90 through the resistor 96, returning to its normal passive state. In this condition, the BATDIAG 94 is not actively measured but continues to remain at a voltage close to the vehicle battery input 90 without introducing significant interference in the system.

The circuit is also designed with fault tolerance in mind. If the BATDIAG 94 experiences a short to the vehicle battery input 90, the system detects it as an overvoltage condition, allowing it to differentiate between normal operation and a fault scenario. If the BATDIAG 94 shorts to ground or another signal, the ADC will detect an abnormal voltage and trigger a fault response. Connector contamination or a high impedance fault could lead to the BATDIAG 94 drifting from the vehicle battery input 90, but such a deviation would be detectable as an unstable or unexpected reading. The presence of the resistor 96 provides that even in the event of an unexpected fault, excessive current flow is prevented. The vehicle battery voltage can be separately measured for comparison purposes using similar circuitry or other standard circuitry.

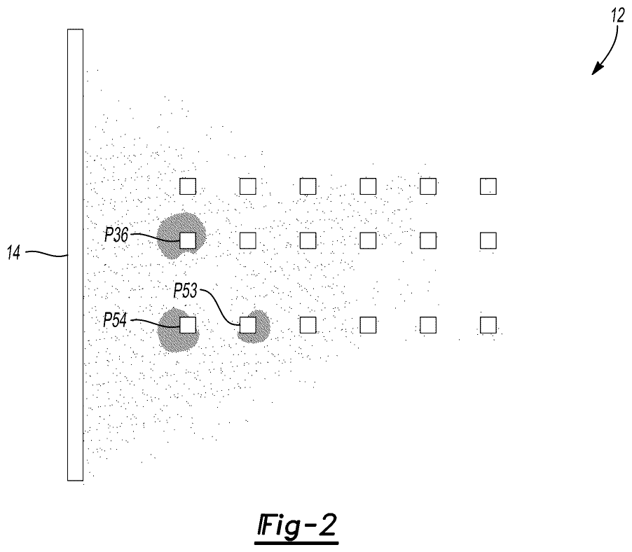

Referring to FIG. 2, electric field intensity is simulated for the connector 12 under circumstances in which the pins P36, P53 are connected with the BATDIAG 94 and the mounting tab 14 is grounded.

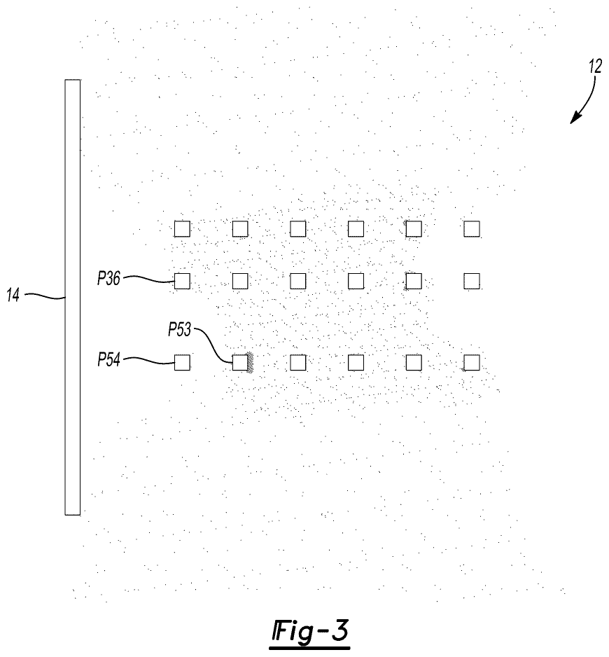

Referring to FIG. 3, electric field intensity is simulated for the connector 12 under circumstances in which the pins P36, P53 and the mounting tab 14 are connected with the BATDIAG 94. Electric field intensity is greater for the pins of interest in FIG. 2 as compared with FIG. 3.

Referring to FIG. 4, a vehicle 112 includes the system 10, a DC power source 114 (e.g., a battery, DC/DC converter, etc.), other power sources 116 (e.g., other batteries, etc.), modules and displays 118 (e.g., other powered components, etc.), and one or more controllers 120 (e.g., processors and memory, etc.). The system 10 is electrically connected with the DC power source 114, other power sources 116, and modules and displays 118. The controllers 120 are in communication with and exert control over the system 10, DC power source 114, other power sources 116, and modules and displays 118.

The controllers 120 communicate through networks like Controller Area Network (CAN), Local Interconnect Network (LIN), or, Ethernet. The controllers 120 exert control by sending Pulse Width Modulation (PWM) signals, logic-level digital outputs, or analog voltage commands to activate or control components such as though described above. Thus, the controllers 120 facilitate assertion of the various signals contemplated herein.

The controllers 120, in addition to initiating the measurement of the BATDIAG 94 as mentioned above, may toggle the system 10 between measurement and non-measurement states to alter the electric fields associated with the pins of interest—potentially reversing or undoing dendritic growth that may have taken place.

The algorithms, methods, and processes described herein can be delivered to or implemented by a computer, controller, or processing device, including dedicated or programmable electronic control units. These algorithms, methods, and processes may be stored as data and executable instructions in various formats, such as information permanently stored on non-writable storage media (e.g., read-only memory devices) or alterably stored on writable storage media (e.g., compact discs, random access memory, or other magnetic and optical media). They can also be implemented as software executable objects. Alternatively, these algorithms, methods, and processes may be realized partially or entirely through hardware components such as application-specific integrated circuits (ASICs), field-programmable gate arrays (FPGAs), state machines, or other suitable hardware devices. In some cases, a combination of firmware, hardware, and software components may be used to implement these functionalities.

While example embodiments described above provide specific implementations, they do not encompass all possible variations of the disclosed technology. The terminology used in this specification serves as a descriptive guide rather than a limitation, and modifications may be made without departing from the broader principles and scope of the disclosure. Furthermore, features from different embodiments may be combined in various ways to create additional implementations.

What is claimed is:

1. A vehicle power system comprising:
a DC power source;
an electrical connector including a plurality of pins; and
circuitry including a line connecting one of the pins with the DC power source such that the DC power source and the one of the pins have a common potential, and configured to toggle a potential of one or more pins adjacent to the one of the pins between a value that tracks the common potential and a reduced value for diagnostic measurement.

2. The vehicle power system of claim 1, wherein the electrical connector further includes a mounting tab and wherein the circuitry is further configured to toggle a potential of the mounting tab between the value that tracks the common potential and the reduced value.

3. The vehicle power system of claim 1, wherein the circuitry further includes a resistor and a line connecting the one or more pins adjacent to the one of the pins with the DC power source through the resistor.

4. The vehicle power system of claim 3, wherein the electrical connector further includes a mounting tab and wherein the line connecting the one or more pins with the DC power source through the resistor further connects the mounting tab with the DC power source through the resistor.

5. The vehicle power system of claim 3, wherein the resistor has a resistance of at least 10 kΩ.

6. The vehicle power system of claim 1, wherein the circuitry further includes one or more switches configured to execute the toggle.

7. The vehicle power system of claim 1, wherein the one of the pins is a corner pin.

8. The vehicle power system of claim 7, wherein the pins are arranged in rows and at least some of the one or more pins adjacent to the one of the pins are in a same one of the rows as the one of the pins.

9. The vehicle power system of claim 7, wherein the pins are arranged in rows and at least some of the one or more pins adjacent to the one of the pins are in a different one of the rows as the one of the pins.

10. The vehicle power system of claim 7, wherein the one or more pins adjacent to the one of the pins are two of the pins.

11. The vehicle power system of claim 1, wherein other of the pins are grounded and the one or more pins adjacent to the one of the pins are between the one of the pins and the other of the pins.

12. The vehicle power system of claim 1, wherein other of the pins are signal pins and the one or more pins adjacent to the one of the pins are between the one of the pins and the other of the pins.

13. The vehicle power system of claim 1, wherein the toggle alters an electric field around the one of the pins and the one or more pins adjacent to the one of the pins.

14. An electrical connector system comprising:
an electrical connector including a plurality of pins and a mounting tab;
a circuit line connecting one of the pins with a DC power source; and
another circuit line including a resistor and connecting the mounting tab and one or more pins adjacent to the one of the pins with the DC power source through the resistor such that a voltage of the mounting tab and the one or more pins adjacent to the one of the pins tracks a voltage of the DC power source.

15. The electrical connector system of claim 14 further comprising one or more switches configured to pull down the another circuit line to reduce a value of the voltage of the mounting tab and the one or more pins adjacent to the one of the pins for diagnostic measurement.

16. The electrical connector system of claim 14, wherein the resistor has a resistance of at least 10 kΩ.

17. The electrical connector system of claim 14, wherein the one of the pins is a corner pin.

18. The electrical connector system of claim 14, wherein other of the pins are grounded or signal pins and the one or more pins adjacent to the one of the pins are between the one of the pins and the other of the pins.

19. An electrical connector system comprising:
a multi-pin electrical connector including a mounting tab; and
circuitry configured to toggle a potential of the mounting tab between a value that tracks a potential of a pin of the multi-pin electrical connector and a reduced value.

20. The electrical connector system of claim 19, wherein the pin is a DC power source input pin.
